(19) United States
(12) Patent Application Publication
(10) Pub. No.: US 2021/0405123 A1
(43) Pub. Date: Dec. 30, 2021

(54) METHOD, APPARATUS, STORAGE MEDIUM AND TERMINAL EQUIPMENT FOR ESTIMATING THE IMPEDANCE OF BATTERY

(71) Applicant: Kai Ming WONG, Hong Kong (HK)

(72) Inventors: Kai Ming WONG, Hong Kong (HK); Yiu Wa LEUNG, Hong Kong (HK); Kwun Yu LAM, Hong Kong (HK)

(21) Appl. No.: 17/327,220

(22) Filed: May 21, 2021

(30) Foreign Application Priority Data
Jun. 24, 2020 (HK) 32020009944.0

(51) Int. Cl. G01R 31/389; G01R 31/36

(52) U.S. Cl. CPC G01R 31/389; G01R 31/3648

(57) ABSTRACT

The disclosure embodiments herein provide a method, an apparatus, a storage medium, and a terminal device for estimating the impedance of a battery. The method includes obtaining an impedance matrix of the battery to be detected, wherein the value of an element of the impedance matrix represents the impedance of the battery and its coordinate in the impedance represents its temperature and quantity of electric charge; detecting the impedance of the battery to obtain a first impedance when its temperature is a first temperature and its quantity of electric charge is a first quantity of electric charge; and updating the impedance matrix of the battery according to the distances between the coordinate forming by the first temperature and the first quantity of electric charge and the coordinates of each element in the impedance matrix, and the first impedance. they can reduce the influence of uncertain factors in the measurement process.

### CROSS-REFERENCE TO RELATED APPLICATIONS

This application claims priority benefits to Hong Kong Patent Application No. 32020009944.0, filed on Jun. 24, 2020. The contents of all of the aforementioned application are incorporated herein by reference.

### TECHNICAL FIELD

The disclosure herein relates to the technical field of battery estimation, and in particular to a method, an apparatus, a storage medium, and a terminal device for estimating the impedance of a battery.

### BACKGROUND

Impedance estimation of lithium-ion batteries can be used for a variety of practical purposes, such as detecting the health of the battery. In the existing technology for measuring the impedance of lithium-ion batteries, voltage and current sensors are mainly involved. Therefore, the reliability of measuring impedance is mainly limited by the performance of voltage and current sensors. Moreover, based on cost and space considerations, very high-performance sensors are generally not used to detect mobile power supplies. At the same time, temperature fluctuations, electromagnetic interference and other factors may cause instability when measuring battery impedance. Therefore, there is an urgent need to propose a solution that can improve the accuracy of battery impedance detection under limited hardware conditions, and can more effectively use devices such as mobile power supplies.

### SUMMARY

The disclosure embodiments herein provide a method, an apparatus, a storage medium, and a terminal device for estimating the impedance of a battery to solve or alleviate one or more technical problem in the prior art.

One aspect of the disclosure embodiments provides a method for estimating the impedance of a battery, comprising:

obtaining an impedance matrix of the battery to be detected, wherein the value of an element of the impedance matrix represents the impedance of the battery and its coordinate in the impedance represents its temperature and quantity of electric charge;

detecting the impedance of the battery to obtain a first impedance when its temperature is a first temperature and its quantity of electric charge is a first quantity of electric charge; and

updating the impedance matrix of the battery according to the distances between the coordinate forming by the first temperature and the first quantity of electric charge and the coordinates of each element in the impedance matrix, and the first impedance.

In some embodiments, said updating the impedance matrix of the battery comprises:

determining a first element in the impedance matrix that is closest to the coordinate forming by the first temperature and the first electrical quantity;

updating the impedance of the first element to:

$$R ( {SOC}_{k 1} , {T}_{k 1} ) = {R}_{k 1} * \sqrt{\frac{{R}_{k}^{′}}{{R}_{k 1}}}$$

wherein SOCₖ₁ represents the quantity of electric charge of the first element, Tₖ₁ represents the temperature of the first element, R(SOCₖ₁, Tₖ₁) represents the updated impedance of the first element, Rₖ₁ represents the impedance of the first element before updating, and R′ₖ represents the first impedance.

In some embodiments, said updating the impedance matrix of the battery further comprises:

for a second element, which is any element other than the first element in the impedance matrix, updating the impedance of the second element to:

$$R ( {SOC}_{k 2} , {T}_{k 2} ) = {R}_{k 2} * {( \frac{{R}_{k}^{′}}{{R}_{k 1}} )}^{n}$$

Wherein SOCₖ₂ represents the quantity of electric charge of the second element, Tₖ₂ represents the temperature of the second element, R(SOCₖ₂, Tₖ₂) represents the updated impedance of the second element, and Rₖ₂ represents the impedance of the second element before updating, and the value of n is: 0<n<0.5.

In some embodiments, the method further comprises:

determining the value of n according to the distance between the coordinate of the second element in the impedance matrix and the coordinate forming by the second temperature and the second quantity of electric charge.

In some embodiments, n is a fixed value.

In some embodiments, the method further comprises initialing the impedance matrix before updating the impedance matrix of the battery, and the initialization comprises:

detecting the impedance of the battery to obtain a second impedance, when its temperature is a second temperature and its quantity of electric charge is a second quantity of electric charge; and

setting the value of element in the impedance matrix of the battery as the second impedance.

In some embodiments, the method further comprises:

determining the second temperature according to the temperature distribution of each element in the impedance matrix; and

determining the second quantity of electric charge according to the distribution of the quantity of electric charge of each element in the impedance matrix.

One aspect of the disclosure embodiments provides a device for estimating impedance of a battery, which comprises:

a matrix obtaining module, configured to obtain an impedance matrix of the battery to be detected, wherein the value of an element of the impedance matrix represents the impedance of the battery and its coordinate in the impedance represent its temperature and quantity of electric charge;

a first detection module, configured to detect the impedance of the battery to obtain a first impedance when its temperature is a first temperature and its quantity of electric charge is a first quantity of electric charge; and

an impedance update module, configured to update the impedance matrix of the battery according to the distances between the coordinate forming by the first temperature and the first quantity of electric charge and the coordinates of each element in the impedance matrix, and the first impedance.

In some embodiments, the device further comprises an initialization module configured to initialize the impedance matrix of the battery before updating, and the initialization module comprises:

A second detection unit, configured to detect the impedance of the battery to obtain a second impedance, when its temperature is a second temperature and its quantity of electric charge is a second quantity of electric charge; and

an impedance setting unit, configured to set the value of element in the impedance matrix of the battery as the second impedance.

One aspect of the disclosure embodiments provides a non-transitory computer-readable storage medium storing a computer program, and when the program is executed by a processor, a method as in any one of the disclosure embodiments is implemented.

One aspect of the disclosure embodiments provides a terminal device, which comprises:

one or more processors;

a memory, configured to store one or more programs;

when the one or more programs are executed by the one or more processors, the one or more processors are caused to implement the method according to any one of the foregoing embodiments.

The method for estimating battery impedance provided by the disclosure embodiments herein can reduce the influence of uncertain factors in the measurement process and improve the accuracy of battery impedance detection. Meanwhile, there is no need to conduct a large amount of impedance characteristic research on the battery before the battery leaves the factory, which reduces the time and cost required for the production and research and development of battery-related products.

The above summary is only for the purpose of description and is not intended to be limiting in any way. In addition to the illustrative aspects, embodiments, and features described above, by referring to the accompanying drawings and the following detailed description, further aspects, embodiments, and features of the disclosure will be easily understood.

### BRIEF DESCRIPTION OF THE DRAWINGS

FIG. 1 shows a schematic flowchart of a method for estimating the impedance of a battery according to an embodiment of the disclosure.

FIG. 2 shows a schematic diagram of the initialization process of the impedance matrix according to an embodiment of the disclosure.

FIG. 3 shows a schematic structural diagram of a device for detecting internal resistance of a battery according to an embodiment of the disclosure.

FIG. 4 shows a terminal device according to an embodiment of the disclosure.

### DETAILED DESCRIPTION OF EMBODIMENTS

In the following, only certain exemplary embodiments are briefly described. As those skilled in the art can realize, the described embodiments may be modified in various different ways without departing from the spirit or scope of the disclosure. Therefore, the drawings and description are to be regarded as illustrative in nature and not restrictive.

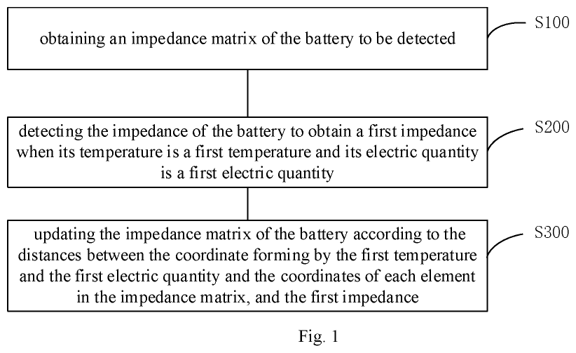

As an exemplary embodiment, FIG. 1 shows a schematic flowchart of a method for estimating the impedance of a battery according to an embodiment of the disclosure. As shown in FIG. 1, the embodiment can be executed by a battery management system or an external detection device. The steps may include S100 to S300, as follows:

S100: obtaining an impedance matrix of the battery to be detected. The value of one element in the impedance matrix represents the impedance of the battery, and its coordinate in the impedance represents its temperature (T) and its quantity of electric charge or power (SOC, state of charge).

The battery impedance is affected by its quantity of electric charge and the temperature of the environment in which it is located. The battery impedance may be different at different quantities of electric charge or temperatures. It can be established an M×N matrix for each battery, which represents the impedance of the battery at its different electric quantities and temperatures. M represents the number of battery temperatures, one row of the matrix represents one temperature value, and the temperatures represented by each row can be different from each other. N represents the number of quantities of electric charge of the battery, one column represents one quantity of electric charge, and the quantity of electric charge represented by each column can be different from each other. Or, M represents the quantity of electric charge of the battery, one row represents one quantity of electric charge, and the quantity of electric charge represented by each row may be different from each other. N represents the number of battery temperatures, one column represents one temperature, and the temperatures represented by each column can be different from each other.

The coordinate of one element in the matrix represents its temperature and quantity of electric charge at this location, and the value of the element represents the battery impedance in this state.

Illustratively, the following Table 1 is an example of an impedance matrix:

TABLE 1

| SOC | T (° C.) | | | | |
|---|---|---|---|---|---|
| (%) | 21 | 23 | 25 | 27 | 29 |
| 20 | R(20, 21) | R(20, 23) | R(20, 25) | R(20, 27) | R(20, 29) |
| 40 | R(40, 21) | R(40, 23) | R(40, 25) | R(40, 27) | R(40, 29) |
| 60 | R(60, 21) | R(60, 23) | R(60, 25) | R(60, 27) | R(60, 29) |
| 80 | R(80, 21) | R(80, 23) | R(80, 25) | R(80, 27) | R(80, 29) |
| 100 | R(100, 21) | R(100, 23) | R(100, 25) | R(100, 27) | R(100, 29) |

In Table 1, the quantities of electric charge SOC are 20, 40, 60, 80, and 100, and the temperatures T are 21, 23, 25, 27, and 29. These values are just for example, there can be other values, or the value can be selected according to the actual.

R (SOCᵢ, Tⱼ) represents the impedance of the battery under its quantity of electric charge SOCᵢ and temperature Tⱼ. i and j are both positive integers, SOCᵢ represents the quantity of electric charge in the i-th row, and Tⱼ represents the temperature in the j-th column. For example, R (20, 21) represents the impedance of the battery under the condition of the remaining 20% of the power and the ambient temperature of 21° C.

As the battery management system cannot store an infinite number of elements of the matrix to represent the quantity of electric charge and temperature, a certain impedance matrix R (SOC, T) is the impedance value recorded under a certain power range and temperature range. If the range of power SOC is D_{SOC} and the range of temperature T is D_{T}, then R (SOC₀, T₀) can be set to record the battery's power in the range of [SOC₀−D_{SOC}/2, SOC₀+DSO_{C}/2] and the temperature in the range of [SOC₀−D_{SOC}/2, SOC₀+D_{SOC}/2]. The impedance under the conditions in the interval [T₀−D_{T}/2, T₀+D_{T}/2]. For example, R(40,23) is the impedance of the recording battery under the conditions of 30<SOC≤50 and 22<T≤24.

In some embodiments, the impedance matrix of the battery can be initialized in advance, or the historical impedance matrix, such as the impedance matrix updated last time, can be used as the initialized impedance matrix.

S200: detecting the impedance of the battery to obtain a first impedance when its temperature is a first temperature and its electric quantity is a first electric quantity.

The two values of the first temperature and the first quantity of electric charge can be randomly selected, or it can be selected from the cordinates of the elements in the impedance matrix. For example, suppose that the temperature of the battery increases, decreases, or is set randomly with the increase of the number of rows of the matrix, and the power of the battery increases, decreases, or is set randomly with the increase of the number of columns of the matrix. For example, it can be selected the coordinate in the middle of the matrix as the first temperature and the quantity of electric charge, and it is also possible to take the average of the temperature and the quantity of electric charge of the matrix respectively as the first temperature and the first quantity of electric charge.

Or, when detecting battery impedance, the current remaining power of the battery can be the first power, and the current temperature of the environment where the battery is located can be the first temperature.

During the impedance detection process, the battery management system can send a signal to the detection module to detect the battery, and the detection module will return a detection result to the battery management system. The detection module can be built in the battery, or it can be an external device. After detecting the impedance of the battery, the external device can disconnect the connection with the battery.

S300: updating the impedance matrix of the battery according to the distances between the coordinate forming by the first temperature and the first electric quantity and the coordinates of each element in the impedance matrix, and the first impedance.

The first temperature and the first quantity of electric charge can be considered as the coordinate or position of a reference point in the matrix, and then respectively calculate the distance between the position of each element in the matrix and the position of this reference point. Then, the value of at least one element in the impedance matrix of the battery can be updated according to the calculated distances and the second impedance.

The calculation of the distance between the position (coordinate) of each element in the calculation matrix and the position (coordinate) of this reference point can be as follows:

For the temperature and quantity of electric charge of each element, calculate the temperature difference between the first temperature and the temperature of the element, and calculate the power difference between the first power and the power of the element, and then calculate a position distance according to the temperature difference and the power difference.

In some embodiments, an impedance matrix obtained based on the above steps can be used for the next update to obtain the latest impedance matrix. This impedance matrix is used as a reference for battery characteristics to reduce the influence of uncertainty caused by multiple measurements and improve the accuracy of battery impedance detection. Moreover, with these disclosure embodiments, there is no need to conduct a large amount of research and testing on the impedance characteristics of the battery before the factory, thereby reducing the production and research and development costs of related products.

In some embodiments, the matrix can be divided into a plurality of sub-matrices to be updated separately, and then combine the updated sub-matrices. It is beneficial to improve the accuracy of battery impedance detection and reduce costs.

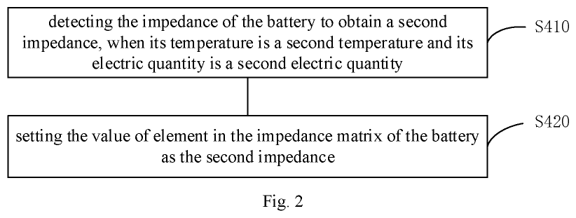

The impedance matrix can be initialized before updating. There may be multiple initialization methods, and only two methods are proposed as examples in the disclosure herein. One is that when the battery has sufficient consistency, it can be assigned a value to each element R (SOCᵢ, Tⱼ) in the impedance matrix. Another way is to measure the impedance of the battery under arbitrary power and temperature conditions or under set power and temperature conditions. Then, assign each element R (SOCᵢ, Tⱼ) to the measured impedance. Specifically, as shown in FIG. 2, for the second way, the process of initializing the impedance matrix may include the following steps:

S410: detecting the impedance of the battery to obtain a second impedance, when its temperature is a second temperature and its electric quantity is a second electric quantity.

S420: setting the value of element in the impedance matrix of the battery as the second impedance.

In this embodiment, the impedance of the battery can be detected under the conditions of the set battery temperature and power, and the detection result is used as the value of each element in the impedance matrix of the battery. Using the initialized impedance matrix as a reference, the impedance matrix is updated at least once in step S200 and S300.

Exemplarily, for the determination of the second temperature and the second quantity of electric charge, the second temperature may be determined according to the temperature distribution corresponding to each element in the impedance matrix. For example, take the median or average of temperatures in the matrix. And the second quantity of electric charge can be determined according to the distribution of quantity of electric charge corresponding to each element in the impedance matrix. For example, take the median or average of quantities of electric charge in the matrix.

Of course, in order to simplify the initialization process, the impedance of the battery is detected in a random environment, and then each element in the impedance matrix is assigned a value of the detection result.

After initialization, the impedance matrix can be updated. The following will exemplarily describe the update process of the impedance matrix: selecting an element from the impedance matrix as a first element, whose position is closest to the first temperature, and then updating the value of the first element to:

$$R ( {SOC}_{k 1} , {T}_{k 1} ) = {R}_{k 1} * \sqrt{\frac{{R}_{k}^{′}}{{R}_{k 1}}}$$

wherein k1 represents the first element, SOCₖ₁ represents the quantity of electric charge of the first element, Tₖ₁ represents the temperature of the first element, and R(SOCₖ₁, Tₖ₁) represents the updated impedance of the first element, Rₖ₁ represents the impedance of the first element before updating, and R′ₖ represents the first impedance.

For the determination of the first element, it can be determine the matrix row closest to the first temperature first (assuming that the row represents the temperature, and the column represents the quantity of electric charge), and then find the element that is closest to the first quantity of electric charge from the elements of the determined matrix row. In some embodiments, taking the first temperature and the first quantity of electric charge as an reference point, calculating the distances between the positions of each element in the matrix and the position of the reference point, and then selecting the element with the closest distance from the reference as the first element.

If there is an element in the matrix whose temperature is the same as the first temperature and the quantity of electric charge is the same as the first quantity of electric charge, then this element is closest to the position of the first temperature and the first quantity of electric charge and can be directly updated as described above.

Assuming that fluctuations are generated due to the influence of other factors when the first impedance is detected, this embodiment updates the first element as described above, which can prevent the first element from fluctuating due to this fluctuation. Then the resistance and impedance saved in the management system will not change too much.

For any element other than the first element, in the disclosure embodiments herein, it is defined as the second element, and the assignment of these second elements can be updated as follows:

$$R ( {SOC}_{k 2} , {T}_{k 2} ) = {R}_{k 2} * {( \frac{{R}_{k}^{′}}{{R}_{k 1}} )}^{n}$$

wherein, k2 represents any element other than the first element in the matrix, that is, the second element. SOCₖ₂ represents the quantity of electric charge of the second element, Tₖ₂ represents the temperature of the second element, R(SOCₖ₂, Tₖ₂) represents the updated impedance of the second element, Rₖ₂ represents the impedance of the second element before updating, the value of n is: 0<n<0.5.

Exemplarily, during an impedance matrix update process, the current remaining power SOC of the battery is 82%, and the current battery temperature T is 25.6° C. The impedance of the battery measured under this condition is 1.2, which is the aforementioned first impedance. Taking the aforementioned Table 1 as an example, the element closest to the SOC of 82% and T of 25.6° C. in the matrix is R(80,25), which is the first element mentioned above. Assume that the value of R(80,25) before updating is 1.1. The updated value of R(80,25) is:

$$1.1 * \sqrt{\frac{1.2}{1.1}} = 1.149$$

For other points in the matrix, the updated

$$R ( {SOC}_{k 2} , {T}_{k 2} ) = {R}_{k 2} * {( \frac{1.2}{1.1} )}^{n} .$$

For the value of n, it can be determined according to the distance between the coordinate forming by the first temperature and the first quantity of electric charge and the coordinate of the second element (corresponding to its temperature and the quantity of electric charge). As the elements in the impedance matrix are relatively close, the aging degree of the battery is relatively similar, and its impedance does not change much with temperature and power, the closer the element is to the position of the first temperature and the first quantity of electric charge, the larger the value of n. the further the element is from the position of the first temperature and the first quantity of electric charge in matrix, the smaller the value of n is.

In some embodiments, for any second element, the value of n may be the same, which is a fixed value.

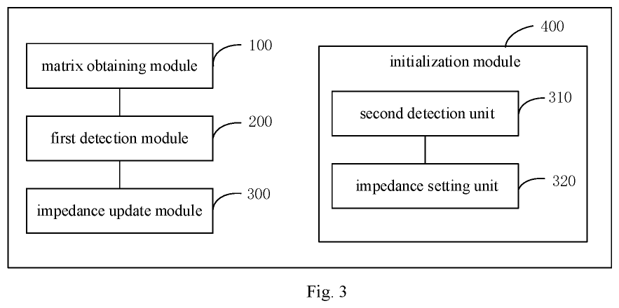

As an exemplary embodiment, FIG. 3 shows a schematic structural diagram of a device for estimating the impendence of a battery according to an embodiment of the disclosure. The detection device shown in FIG. 3 may comprises:

a matrix obtaining module 100, configured to obtain an impedance matrix of the battery to be detected, wherein the value of an element of the impedance matrix represents the impedance of the battery and its coordinate in the impedance represent its temperature and quantity of electric charge;

a first detection module 200, configured to detect the impedance of the battery to obtain a first impedance when its temperature is a first temperature and its quantity of electric charge is a first quantity of electric charge.

an impedance updating module 300, configured to update the impedance matrix of the battery according to the distances between the coordinate forming by the first temperature and the first quantity of electric charge and the coordinates of each element in the impedance matrix, and the first impedance.

In some embodiments, the device further comprises an initialization module 400, configured to initialize the impedance matrix of the battery before updating, and the initialization module 400 comprises:

a second detection unit 410, configured to detect the impedance of the battery to obtain a second impedance, when its temperature is a second temperature and its quantity of electric charge is a second quantity of electric charge.

an impedance setting unit 420, configured to set the value of element in the impedance matrix of the battery as the second impedance.

In some embodiments, the foregoing device may further include:

an temperature determining unit, configured to determine the second temperature according to the temperature distribution of each element in the impedance matrix.

an power determining unit, configured to determine the second quantity of electric charge according to the distribution of the quantity of electric charge of each element in the impedance matrix.

In some embodiments, the aforementioned impedance update module 300 may include a first update unit, which is configured to:

determine a first element in the impedance matrix that is closest to the coordinate forming by the first temperature and the first electrical quantity;

update the impedance of the first element to:

$$R ( {SOC}_{k 1} , {T}_{k 1} ) = {R}_{k 1} * \sqrt{\frac{{R}_{k}^{′}}{{R}_{k 1}}}$$

wherein SOCₖ₁ represents the quantity of electric charge of the first element, Tₖ₁ represents the temperature of the first element, R(SOCₖ₁, Tₖ₁) represents the updated impedance of the first element, Rₖ₁ represents the impedance of the first element before updating, and R′ₖ represents the first impedance.

In some embodiments, the aforementioned impedance update module 300 may include a second update unit, which is configured to:

for a second element, which is any element other than the first element in the impedance matrix, update the impedance of the second element to:

$$R ( {SOC}_{k 2} , {T}_{k 2} ) = {R}_{k 2} * {( \frac{{R}_{k}^{′}}{{R}_{k 1}} )}^{n}$$

wherein SOCₖ₂ represents the quantity of electric charge of the second element, Tₖ₂ represents the temperature of the second element, R(SOCₖ₂, Tₖ₂) represents the updated impedance of the second element, Rₖ₂ represents the impedance of the second element before updating, and the value of n is: 0<n<0.5.

In some embodiments, the above-mentioned impedance update module 300 may further include a value unit configured to: determine the value of n according to the distance between the coordinate forming by the first temperature and the first quantity of electric charge and the coordinate of the second element (corresponding to its temperature and the quantity of electric charge).

In some embodiments, the value of n may be a fixed value.

The function of the device can be realized by hardware, or can be realized by hardware executing corresponding software. The hardware or software includes one or more modules corresponding to the above-mentioned functions.

As an example of the disclosure herein, it provides a design: the structure for battery impedance detection includes a processor and a memory, the memory is configured to perform the program corresponding to the foregoing battery impendence detection by the battery impendence detection device, and the processor is configured to execute the program stored in the memory. The device for detecting the impendence of the battery further comprises a communication interface, which is configured to communicate the detection device with other equipment or a communication network.

The device also comprises:

a communication interface 23, which is configured to communicate the processor 22 to external devices;

a memory 21, which may include a high-speed RAM memory, and may also include a non-volatile memory (non-volatile memory), for example, at least one magnetic disk memory.

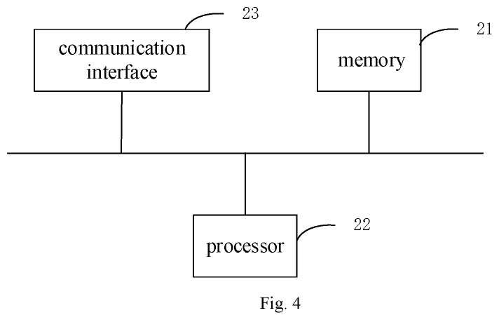

If the memory 21, the processor 22, and the communication interface 23 are implemented independently, they can be connected to each other through a bus and complete mutual communication. The bus can be an industry standard architecture (ISA, Industry Standard Architecture) bus, a peripheral device interconnection (PCI, Peripheral Component) bus, or an extended industry standard architecture (EISA, Extended Industry Standard Component) bus, etc. The bus can be divided into address bus, data bus, control bus and so on. For ease of representation, only one thick line is used in FIG. 4 to represent, but it does not mean that there is only one bus or one type of bus.

Optionally, in specific implementation, if the memory 21, the processor 22, and the communication interface 23 are integrated on one chip, they may communicate with each other by internal interfaces.

In the description of this specification, descriptions with reference to the terms “one embodiment”, “some embodiments”, “examples”, “specific examples”, or “some examples” etc. mean specific features described in conjunction with the embodiment or example, The structure, materials, or characteristics are included in at least one embodiment or example of the present application. Moreover, the described specific features, structures, materials or characteristics can be combined in any one or more embodiments or examples in a suitable manner. In addition, those skilled in the art can combine and combine the different embodiments or examples and the features of the different embodiments or examples described in this specification without contradicting each other.

In addition, the terms “first” and “second” are only used for descriptive purposes, and cannot be understood as indicating or implying relative importance or implicitly indicating the number of indicated technical features. Therefore, the features defined with “first” and “second” may explicitly or implicitly include at least one of the features. In the description of the present application, “multiple” means two or more than two, unless otherwise specifically defined.

Any process or method description in the flowchart or described in other ways herein can be understood as a module, segment or part of code that includes one or more executable instructions for implementing specific logical functions or steps of the process, And the scope of the preferred embodiments of the present application includes additional implementations, which may not be in the order shown or discussed, including performing functions in a substantially simultaneous manner or in the reverse order according to the functions involved. This should be It is understood by those skilled in the art to which the embodiments of the present application belong.

The logic and/or steps represented in the flowchart or described in other ways herein, for example, can be considered as a sequenced list of executable instructions for implementing logic functions, and can be embodied in any computer-readable medium, For use by instruction execution systems, devices, or equipment (such as computer-based systems, systems including processors, or other systems that can fetch and execute instructions from instruction execution systems, devices, or equipment), or combine these instruction execution systems, devices Or equipment. For the purposes of this specification, a “computer-readable medium” can be any device that can contain, store, communicate, propagate, or transmit a program for use by an instruction execution system, device, or device or in combination with these instruction execution systems, devices, or devices.

The computer-readable medium in the embodiment of the present application may be a computer-readable signal medium or a computer-readable storage medium, or any combination of the two. More specific examples of computer-readable storage media include at least (non-exhaustive list) the following: electrical connections (electronic devices) with one or more wiring, portable computer disk cases (magnetic devices), random access memory (RAM), read-only memory (ROM), erasable and editable read-only memory (EPROM or flash memory), fiber optic devices, and portable read-only memory (CDROM). In addition, the computer-readable storage medium may even be paper or other suitable medium on which the program can be printed, because it can be used for example by optically scanning the paper or other medium, and then editing, interpreting or other suitable means when necessary. Processing is performed to obtain the program electronically and then store it in the computer memory.

In the embodiments of the present application, a computer-readable signal medium may include a data signal propagated in a baseband or as a part of a carrier wave, and a computer-readable program code is carried therein. This propagated data signal can take many forms, including but not limited to electromagnetic signals, optical signals, or any suitable combination of the foregoing. The computer-readable signal medium may also be any computer-readable medium other than the computer-readable storage medium, and the computer-readable medium may send, propagate, or transmit a program used in or in combination with an instruction execution system, input method, or device. The program code contained on the computer-readable medium can be transmitted by any suitable medium, including but not limited to: wireless, wire, optical cable, radio frequency (RF), etc., or any suitable combination of the foregoing.

It should be understood that each part of this application can be implemented by hardware, software, firmware, or a combination thereof. In the above embodiments, multiple steps or methods can be implemented by software or firmware stored in a memory and executed by a suitable instruction execution system. For example, if it is implemented by hardware, as in another embodiment, it can be implemented by any one or a combination of the following technologies known in the art: Discrete logic circuits, application-specific integrated circuits with suitable combinational logic gates, programmable gate array (PGA), field programmable gate array (FPGA), etc.

Those of ordinary skill in the art can understand that all or part of the steps carried in the method of the foregoing embodiments can be implemented by a program instructing relevant hardware. The program can be stored in a computer-readable storage medium, and the program can be executed when the program is executed. Including one of the steps of the method embodiment or a combination thereof.

In addition, each functional unit in each embodiment of the present application may be integrated into one processing module, or each unit may exist alone physically, or two or more units may be integrated into one module. The above-mentioned integrated modules can be implemented in the form of hardware or software functional modules. If the integrated module is implemented in the form of a software function module and sold or used as an independent product, it can also be stored in a computer-readable storage medium. The storage medium can be a read-only memory, a magnetic disk or an optical disk, etc.

The above are only specific implementations of this application, but the scope of protection of this application is not limited thereto. Any person skilled in the art can easily think of various changes or substitutions within the technical scope disclosed in this application. These should be covered in the scope of protection of this application. Therefore, the protection scope of this application shall be subject to the protection scope of the claims.

What is claimed is:

1. A method for estimating impedance of a battery, comprising:
obtaining an impedance matrix of the battery to be detected, wherein the value of an element of the impedance matrix represents the impedance of the battery and its coordinate in the impedance represents its temperature and quantity of electric charge;
detecting the impedance of the battery to obtain a first impedance when its temperature is a first temperature and its quantity of electric charge is a first quantity of electric charge; and
updating the impedance matrix of the battery according to the distances between the coordinate forming by the first temperature and the first quantity of electric charge and the coordinates of each element in the impedance matrix, and the first impedance.

2. The method according to claim 1, wherein said updating the impedance matrix of the battery comprises:
determining a first element in the impedance matrix that is closest to the coordinate forming by the first temperature and the first quantity of electric charge;
updating the impedance of the first element to:
$$R ( {SOC}_{k 1} , {T}_{k 1} ) = {R}_{k 1} * \sqrt{\frac{{R}_{k}^{′}}{{R}_{k 1}}}$$
wherein SOCₖ₁ represents the quantity of electric charge of the first element, Tₖ₁ represents the temperature of the first element, R(SOCₖ₁, Tₖ₁) represents the updated impedance of the first element, Rₖ₁ represents the impedance of the first element before updating, and R′ₖ represents the first impedance.

3. The method according to claim 2, wherein said updating the impedance matrix of the battery further comprises:
for a second element, which is any element other than the first element in the impedance matrix, updating the impedance of the second element to:
$$R ( {SOC}_{k 2} , {T}_{k 2} ) = {R}_{k 2} * {( \frac{{R}_{k}^{′}}{{R}_{k 1}} )}^{n}$$
Wherein SOCₖ₂ represents the quantity of electric charge of the second element, Tₖ₂ represents the temperature of the second element, R(SOCₖ₂, Tₖ₂) represents the updated impedance of the second element, Rₖ₂ represents the impedance of the first element before updating, and the value of n is: 0<n<0.5.

4. The method according to claim 3, wherein the method further comprises:
determining the value of n according to the distance between the coordinate of the second element in the impedance matrix and the coordinate forming by the second temperature and the second quantity of electric charge.

5. The method according to claim 3, wherein n is a fixed value.

6. The method according to claim 1, wherein initialing the impedance matrix before updating the impedance matrix of the battery, and the initialization comprises:
detecting the impedance of the battery to obtain a second impedance, when its temperature is a second temperature and its quantity of electric charge is a second quantity of electric charge; and
setting the value of element in the impedance matrix of the battery as the second impedance.

7. The method according to claim 6, further comprising:
determining the second temperature according to the temperature distribution of each element in the impedance matrix; and
determining the second quantity of electric charge according to the distribution of the quantity of electric charge of each element in the impedance matrix.

8. An apparatus for estimating impedance of a battery, which comprises:
a matrix obtaining module, configured to obtain an impedance matrix of the battery to be detected, wherein the value of an element of the impedance matrix represents the impedance of the battery and its coordinate in the impedance represents its temperature and quantity of electric charge;
a first detection module, configured to detect the impedance of the battery to obtain a first impedance when its temperature is a first temperature and its quantity of electric charge is a first quantity of electric charge; and
an impedance update module, configured to update the impedance matrix of the battery according to the distances between the coordinate forming by the first temperature and the first quantity of electric charge and the coordinates of each element in the impedance matrix, and the first impedance.

9. The apparatus according to claim 8, wherein the device further comprises an initialization module, configured to initialize the impedance matrix of the battery before updating, and the initialization module comprises:
a second detection unit, configured to detect the impedance of the battery to obtain a second impedance, when its temperature is a second temperature and its quantity of electric charge is a second quantity of electric charge; and
an impedance setting unit, configured to set the value of element in the impedance matrix of the battery as the second impedance.

10. A terminal device, comprising:
one or more processors; and
a memory, configured to store one or more programs;
when the one or more programs are executed by the one or more processors, the one or more processors are caused to implement the method according to claim 1.
